(19) United States
(12) Patent Application Publication
(10) Pub. No.: US 2008/0073203 A1
(43) Pub. Date: Mar. 27, 2008

(54) Method of making first surface mirror with oxide graded reflecting layer structure

(75) Inventors: Hong Wang, Shanghai (CN); Brent Boyce, Novi, MI (US); Francis Wuillaume, Plymouth, MI (US)

Correspondence Address: NIXON & VANDERHYE, PC, 901 NORTH GLEBE ROAD, 11TH FLOOR, ARLINGTON, VA, 22203, US

(73) Assignee: Guardian Industries Corp., Auburn Hills, MI (US)

(21) Appl. No.: 11/523,092

(22) Filed: Sep. 19, 2006

(51) Int. Cl. B05D 5/06; C23C 14/32

(52) U.S. Cl. 204/192.1; 427/162

(57) ABSTRACT

A method of making a mirror such as a first-surface mirror (FSM) is provided. The mirror includes a reflecting layer structure made of a visible light reflecting material such as aluminum (Al) or the like. At least part of the reflecting layer structure is oxide graded, continuously or discontinuously, so as be more oxided at one or both sides of the layer structure. In other words, the reflecting layer structure is more or entirely metallic at a central portion thereof, and more oxided at the top and/or bottom side(s) thereof. In certain example embodiments, such first surface mirrors may be used in the context of projection televisions, or in any other suitable application.

This application relates to a method of making a first-surface mirror (FSM) including a reflecting layer comprising a visible light reflecting material such as aluminum (Al). In certain example embodiments of this invention, at least part of the reflecting layer is oxide graded, continuously or discontinuously, so that the reflecting layer is more oxided at one or both sides thereof than at a central portion of the layer which may or may not be oxided. In other words, the reflecting layer is more metallic at a central portion thereof, and more oxided at the top and/or bottom portion(s) thereof. In certain example embodiments, such first surface mirrors may be used in the context of a projection television (PTV) apparatus, or any other suitable application.

### BACKGROUND AND SUMMARY OF THE INVENTION

Mirrors for various uses are known in the art. For example, see U.S. Pat. Nos. 5,923,464 and 4,309,075 (all hereby incorporated herein by reference). Mirrors are also known for use in projection televisions and other suitable applications. In the projection television context, see for example U.S. Pat. Nos. 6,275,272, 5,669,681 and 5,896,236 (all hereby incorporated herein by reference).

One type of mirror is a second or back surface mirror (most common), while another type of mirror is a first or front surface mirror (less common). Back surface mirrors typically include a glass substrate with a reflective coating on a back surface thereof (i.e., not on the front surface which is first hit by incoming light). Incoming light passes through the glass substrate before being reflected by the coating in a second surface mirror. Thus, reflected light passes through the glass substrate twice in back or second surface mirrors; once before being reflected and again after being reflected by the reflective coating on its way to a viewer. In certain instances, passing through the glass substrate twice can create ambiguity in directional reflection and imperfect reflections may sometimes result. Mirrors such as bathroom mirrors, bedroom mirrors, and architectural mirrors are typically back or second surface mirrors so that the glass substrate can be used to protect the reflective coating provided on the rear surface thereof.

In applications where more accurate and/or complete reflections are desired, front (or first) surface mirrors are often used. In front/first surface mirrors (FSMs), a reflective coating is provided on the front surface of the glass substrate so that incoming light is reflected by the coating before it passes through the glass substrate (e.g., see FIG. 1). Since the light to be reflected does not have to pass through the glass substrate in first surface mirrors (in contrast to rear surface mirrors), first surface mirrors generally have higher light reflectance than do rear surface mirrors, and no double reflected image. Example front surface mirrors (or first surface mirrors) are disclosed in U.S. Pat. Nos. 5,923,464 and 4,780,372 (both incorporated herein by reference).

Many first surface mirror reflective coatings include a dielectric layer(s) provided on the glass substrate over a visible light reflective layer (e.g., Al). Unfortunately, when the coating becomes scratched or damaged in a front surface mirror, this affects reflectivity in an undesirable manner as light must pass through the scratched or damaged layer(s) twice before reaching the viewer (this is not the case in back/rear surface mirrors where the reflective layer is protected by the glass). Coatings typically used in this regard are not very durable, and are easily scratched or otherwise damaged leading to reflectivity problems. Thus, it can be seen that front/first surface mirrors are very sensitive to scratching. Other possible cosmetic problems associated with first surface mirrors include pinhole formations, corrosion, adhesion, and/or reflectivity level.

For example, prior art FIG. 1 of the instant application illustrates a first surface mirror including glass/Al/SiO₂/TiO₂, where the aluminum (Al) visible light reflecting layer is deposited directly onto the glass substrate. The metal light reflecting Al layer may be 400 angstroms (Å) thick, the SiO₂ layer may be 880 angstroms thick, and the TiO₂ layer may be 440 angstroms thick. Such mirrors suffer from problems such as poor adhesion, pinholes, poor scratch and abrasion resistance, and other durability and cosmetic problems. These durability problems are particularly evident when float glass (soda lime silica glass) is used as the substrate.

Unfortunately, the durability of first surface mirrors as shown in FIG. 1 is problematic. First, there is poor adhesion between the metal layer (Al) and the glass substrate. Second, there is poor adhesion between the metal layer (Al) and the dielectric overcoat (SiO₂/TiO₂). Third, if a metal layer such as Cr is added below the Al between the Al and the glass substrate, corrosion of metal(s) tends to be caused by electrochemical reactions due to the flow of electrons among metals having different free energy if a multiple-layered metal (e.g., Cr/Al) is used to improve metal/glass adhesion. Thus, such first surface mirrors suffer from yield loss on mechanical durability tests due to the delamination of Al from the glass and/or silicon oxide. In the third situation, where a metal layer such as Cr is added below the Al between the Al and the glass substrate, delamination of the coating from the glass is improved but the product sometimes fails the salt fog test due to metal corrosion.

It will be apparent from the above that there exists a need in the art for a first/front surface mirror that is less susceptible to scratching, corrosion, pinhole formations, and/or the like.

In order to improve durability, it has been known to add sputter-deposited aluminum oxide below the sputter-deposited aluminum of the reflecting layer (e.g., see commonly owned U.S. Patent Publication 2006/0063010, hereby incorporated herein by reference). However, such an approach typically involves an additional sputtering cathode dedicated to forming the aluminum oxide. Accordingly, such an approach not only increases equipment and production costs, but also faces a process challenge in attempting to make a proper composition gradient from fairly fully oxidic on the oxide side to mostly or fully metallic in the metal area in a very small thickness.

Certain example embodiments of this invention relate to an improved technique for making a durable coated article such as a first surface mirror (FSM) or the like. In certain example embodiments, a first surface mirror includes a reflecting layer comprising a visible light reflecting material such as aluminum (Al) or the like. In certain example embodiments, at least part of the reflecting layer is oxide graded, continuously or discontinuously, so as be more oxided at one or both sides of the reflecting layer than at a central portion thereof which may be a primary light reflecting portion of the reflecting layer. In other words, the reflecting layer is more metallic at a central portion thereof, and more oxided at the top and/or bottom side(s) thereof. Small amounts of oxygen may or may not be provided in the central portion of the reflecting layer in different example embodiments of this invention.

In certain example embodiments of this invention, such a mirror may be made without adding significant amounts of equipment and/or cost to an in-line sputter coating system. For a cathode(s) sputtering pure metal (e.g., aluminum), the metal atom flux is mainly concentrated in a high flux area proximate the middle of the cathode(s). This flux diminishes toward the front and back edges of the cathode(s), thereby forming lower flux areas. Taking advantage of this flux distribution below or proximate one or a series of sputtering cathodes, adhesion metal oxide layer portions can be made in a simple and efficient manner by directing a small amount of reactive oxygen gas (optionally, in addition to an inert gas such as argon) proximate one or both of the lower flux areas. Meanwhile, an inert gas such as argon is directed (with less or no oxygen) toward and provided in the high flux area. Such an asymmetric gas flow distribution proximate the sputtering cathode(s) allows at least part of the reflecting layer to be oxide graded, continuously or discontinuously, so that the reflecting layer is more oxided at one or both sides thereof (i.e., at the bottom and/or top sides thereof) than at a central portion thereof.

When such an asymmetric gas flow is provided by introducing oxygen gas into one or both low flux areas, and introducing less or no oxygen gas into the high flux area(s), the glass substrate (or a given portion thereof) moving adjacent (e.g., under) the sputtering cathode(s) first encounters a first low flux area. In this first low flux area, reactive oxygen gas (optionally in combination with an inert gas such as argon) may be present in an amount sufficient to form an oxided layer portion (e.g., aluminum oxide) which forms a bottom portion of the reflecting layer. This metal oxide bottom portion of the reflecting layer may be located directly on and contacting a surface of the glass substrate in certain example instances. In particular, the metal (e.g., Al) sputtered from the cathode(s) reacts with the oxygen as it moves (e.g., falls) toward the substrate thereby forming a metal oxide (e.g., aluminum oxide) on the substrate. This oxided layer portion forming the bottom portion of the reflecting layer may be fully oxided (e.g., Al₂O₃), substantially fully oxided, or less oxided in different example embodiments of this invention.

As the glass substrate (or a given portion thereof) moves further, it then encounters the high flux area which may be located beneath a central portion of the sputtering cathode(s) used for depositing the visible light reflecting layer. There is less or no oxygen gas in this high flux area, with most or all of the gas in this high flux area typically being an inert gas(es) such as argon (Ar) or the like. The oxygen gas content in this high flux area may be negligible, or substantially negligible, in certain example embodiments. Thus, the metal (e.g., Al) sputtered from the cathode target(s) and which passes through the high flux area does not react with oxygen (or not much) as it moves (e.g., falls) toward the substrate thereby forming a metallic or substantially metallic layer portion on the substrate. This metallic or substantially metallic layer portion forms a central portion of the reflecting layer, which may be a primary visible light reflecting portion of the reflecting layer. Thus, it will be appreciated that in certain example embodiments of this invention, a thin gradient oxide layer portion may be formed in a bottom portion of the reflecting layer, transforming in composition from a full or substantially full oxide at the bottom of the reflecting layer to purely metallic or substantially metallic at a more central portion of the reflecting layer.

Then, as the glass substrate (or a given portion thereof) moves further adjacent (e.g., under) the sputtering cathode(s), it encounters another low flux area (e.g., the high flux area is between first and second low flux areas). As with the first low flux area, in this another or second low flux area, reactive oxygen gas (optionally in combination with an inert gas such as argon) may be present in an amount sufficient to form a significantly oxided layer portion (e.g., aluminum oxide) which forms a top portion of the reflecting layer. In particular, the metal (e.g., Al) sputtered from the cathode(s) reacts with the oxygen in this second low flux area as the metal moves (e.g., falls) toward the substrate through this second low flux area thereby forming metal oxide (e.g., aluminum oxide) on the substrate. This oxided layer portion forming the top portion of the reflecting layer may be fully oxided (e.g., Al₂O₃), substantially fully oxided, or less oxided in different example embodiments of this invention. Optionally, either the top or bottom layer portion of the reflecting layer may be metallic, instead of oxided, in certain alternative example embodiments of this invention by providing no oxygen gas in one of the two low flux areas.

Because the center section of the cathode(s) area is wider and the flux is so dominating therein, the majority of the reflecting layer is formed as the metallic or substantially metallic portion via the high flux area. In other words, in certain example embodiments of this invention, the metallic or substantially metallic central layer portion formed via the high flux area is much thicker than are each of the thinner metal oxide layer portion(s) formed as top and/or bottom portions of the reflecting layer via the low flux area(s). The result, in certain example embodiments, may be a purely metallic or substantially metallic layer portion sandwiched between thin metal oxide layer portions which may optionally be oxidation graded (less oxided closer to the metallic central portion of the reflecting layer, and oxided to a greater extent farther from the metallic central portion). It has been found that providing such metal oxide portion(s) on one or both sides of the metallic central portion is advantageous in that it significantly improves durability of the mirror.

In certain example embodiments, the metal in the metal oxide layer portion(s) is the same metal as the metal in the central portion of the reflecting layer, thereby improving durability and manufacturability. This metal may be Al, or any other suitable reflecting metal provided in sufficient thickness to reflect substantial amounts of visible light, in different example embodiments of this invention.

In certain example embodiments of this invention, first surface mirrors made in such a manner may be used in projection televisions, copiers, scanners, bar code readers, vehicle mirrors, overhead projectors, and/or any other suitable applications.

In certain example embodiments of this invention, there is provided a method of making a mirror (first surface or other type of mirror), the method comprising: causing a substrate to move past at least first and second sputtering targets, wherein a first low flux area is located at an input side of the first target, a high flux area is located below the first and second sputtering targets, and a second low flux area is located at an output side of the second target; sputter-depositing a reflective layer, for reflecting visible light, on the substrate using at least the first and second sputtering targets; and introducing at least oxygen gas into one or both of the low flux areas and introducing an inert gas into the high flux area as the glass substrate is moving past the sputtering targets, so as to sputter deposit the reflective layer on the substrate in a manner such that the reflective layer of the mirror has a metallic or substantially metallic central portion that is formed using both of the first and second targets and a metal oxide portion located at a bottom portion and/or top portion of the reflective layer, the metal oxide portion of the reflective layer comprising an oxide of the same metal provided in the central portion of the reflective layer; and depositing at least a first dielectric layer on the substrate over at least the reflective layer.

In other example embodiments of this invention, there is provided a method of making a first surface mirror, the method comprising: causing a glass substrate to move past at least one rotating sputtering target; sputter-depositing a reflective layer, for reflecting visible light, on the glass substrate using the at least one rotating sputtering target; introducing at least oxygen gas into a low flux area proximate a first side of the sputtering target as the glass substrate is moving past the sputtering target, and introducing at least an inert gas into a high flux area below the sputtering target as the glass substrate is moving past the sputtering target, so as to sputter deposit the reflective layer in a manner such that the reflective layer of the mirror is oxidation graded so that the reflective layer is more oxided in an area closer to the glass substrate than in a central portion of the reflective layer; and depositing at least a first dielectric layer on the glass substrate over at least the reflective layer.

### BRIEF DESCRIPTION OF THE DRAWINGS

FIG. 1 is a cross sectional view of a conventional first surface mirror.

FIG. 2 is a cross sectional view of a first surface mirror according to an example embodiment of this invention.

FIG. 3 is a schematic cross sectional view showing a reflecting layer of a first surface mirror according to an example embodiment of this invention being sputter deposited in an oxide graded manner so as to have oxided layer portions at top and bottom sides of the reflecting layer.

FIG. 4 is a schematic diagram illustrating a first surface mirror according to an example embodiment of this invention being used in the context of a projection television apparatus.

### DETAILED DESCRIPTION OF EXAMPLE EMBODIMENTS OF THE INVENTION

The instant invention relates to a mirror that may be used in the context of projection televisions (PTVs), copiers, scanners, bar code readers, overhead projectors, and/or any other suitable applications. In certain embodiments, the mirror is a first surface (FSM) including a reflecting layer comprising a visible light reflecting material such as aluminum (Al). At least part of the reflecting layer is oxide graded, continuously or discontinuously, progressively or non-progressively, so that the reflecting layer is more oxided at one or both sides thereof than at a central portion thereof which may or may not be oxided. In other words, the reflecting layer is more metallic at a central portion thereof, and more oxided at the top and/or bottom portion(s) thereof. The reflective layer (e.g., using as the visible light reflecting material Al, Cr, Ni, Cu, mixtures thereof, and/or the like) may be covered by at least one dielectric layer(s) such as SiO₂ and/or TiO₂, although other suitable dielectric materials may also or instead be used. The metal in the top/bottom metal oxide layer portion(s) is the same metal as the metal in the metallic central portion of the reflecting layer, thereby improving durability and manufacturability. Thus, when the central portion of the reflective layer is of metallic Al, then the top and/or bottom metal oxide portions of the reflective layer are of an oxide of Al. As another example, when the central portion of the reflective layer is of metallic Cr, then the top and/or bottom metal oxide portions of the reflective layer are of an oxide of Cr.

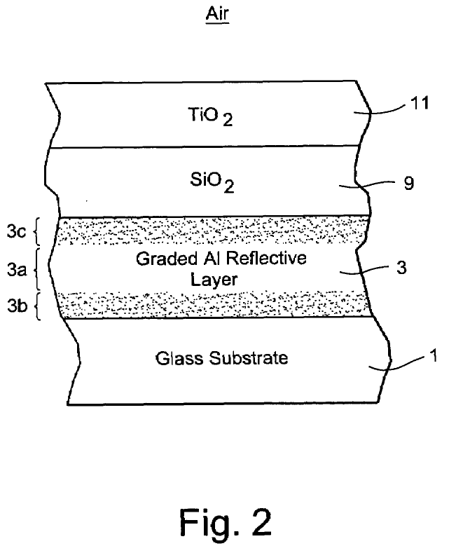

FIG. 2 is a cross sectional view of a first surface mirror according to an example embodiment of this invention. The first surface mirror of FIG. 2 includes glass substrate 1, visible light reflecting layer 3, dielectric layer 9 and dielectric overcoat layer 11. Glass substrate 1 may be from about 1-10 mm thick in different embodiments of this invention, and may be any suitable color (e.g., gray, clear, green, blue, etc.). In certain example instances, glass (e.g., soda lime silica type glass) substrate 1 is from about 1-5 mm thick, most preferably about 3 mm thick. When substrate 1 is glass, it may have an index of refraction value “n” of from about 1.48 to 1.53 (most preferably about 1.51 to 1.52).

Reflective layer 3 may be based on aluminum (Al) or any other suitable light reflective material provided in sufficient thickness to reflect substantial amounts of visible light for mirror applications. Reflective layer 3 reflects the majority of incoming visible light before it reaches glass substrate 1 and directs it toward a viewer or the like away from the glass substrate, so that the mirror is referred to as a first surface mirror. In certain embodiments, reflective layer 3 has an index of refraction value “n” (at 550 nm) of from about 0.05 to 1.5, more preferably from about 0.05 to 1.0. When layer 3 is based on Al, the index of refraction “n” of the layer 3 may be about 0.8 to 1.25, more preferably from about 0.8 to 0.9, but it also may be as low as about 0.1 when the layer 3 is of Ag for instance. In certain example embodiments of this invention, the reflective layer 3 may be sputtered onto the substrate 1 using one or more C-MAG rotatable cathode sputtering targets (e.g., the sputtering material of the targets is Al when the layer 3 is based on Al; such Al targets may or may not be doped with other material in different instances); an example sputtering power/pressure which may be used is 6 kW per C-MAG power, and a pressure of 3 mTorr. Reflective layer 3 in certain embodiments of this invention has an average (p- and/or s-polarization in certain instances) reflectance of at least about 75% in the 550 nm region as measured on a Perkin Elmer Lambda 900 or equivalent spectrophotometer, more preferably at least 80% at any incident angle. Moreover, in certain embodiments of this invention, reflective layer 3 need not be completely opaque, as it may have a small transmission in the aforesaid wavelength region of from 0.1 to 10%, more preferably from about 0.5 to 1.5%.

Reflective layer 3 may be from about 30-150 nm thick in certain embodiments of this invention, more preferably from about 30-90 nm thick, even more preferably from about 35-60 nm thick, with an example thickness being about 40 nm when Al is used as the base metal for layer 3.

Dielectric layers 9 and 11 may be made of any suitable material, although in certain example embodiments of this invention dielectric layer 9 is of or includes silicon oxide (e.g., SiO₂, or other suitable stoichiometry) and layer 11 is of or includes titanium oxide (e.g., TiO₂, or other suitable stoichiometry).

In certain example embodiments of this invention, dielectric layer 11 has a higher index of refraction “n” than does dielectric layer 9; and layer 9 has a higher index of refraction “n” than does reflective layer 3. In certain example embodiments, layer 11 has an index of refraction “n” of from about 2.2 to 2.6, more preferably from about 2.3 to 2.5; dielectric layer 9 has an index “n” of from about 1.4 to 1.8, more preferably from about 1.4 to 1.6; and reflective layer 3 has an index “n” of from about 0.1 to 1.2, more preferably from about 0.8 to 1.25.

As shown in FIG. 2, the reflective layer 3 includes a metallic or substantially metallic central portion 3a, a bottom portion 3b, and a top portion 3c. One or both of portions 3b, 3c is oxided in certain example embodiments of this invention, optionally in an oxide graded manner so as to be more metallic (and less oxided) closer to central portion 3a. The dots in FIG. 2 in layer 3 represent the presence of oxygen in the reflective layer 3 (both portions 3b and 3c are shown as oxided in FIG. 2, although this is not necessary).

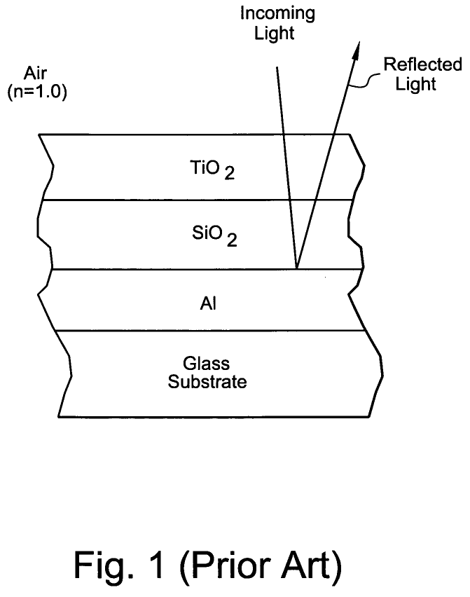

In certain example embodiments of this invention, it has been found that providing metal oxide (e.g., aluminum oxide) in layer portion 3b immediately under and contacting the metallic or substantially metallic reflective layer portion 3a (e.g., of Al) allows for the durability of the resulting mirror to be significantly improved. In particular, the aforesaid durability problems of the FIG. 1 prior art can be greatly reduced by providing such a metal oxide layer portion 3b under the more metallic portion and light reflecting portion 3a. The aluminum oxide of layer portion 3b is a good nucleation layer portion for the metallic portion 3a of the reflective layer 3, and also adheres well to glass 1 and can tolerate imperfect cleanliness on the glass surface. Thus, the introduction of the aluminum oxide in layer portion 3b between the metallic portion 3a and the glass substrate 1 promotes better adhesion of the metal to the glass without the trade-off of significant corrosion problems. Moreover, because the metal oxide nucleation layer portion 3b (e.g., aluminum oxide of any suitable stoichiometry such as Al₂O₃) contains a primary metal (e.g., Al) which is the same as the primary metal of the metallic or more metallic layer portion 3a, no new material needs to be introduced into the fabrication process. Moreover, potential corrosion caused by free energy difference between different metals is reduced and/or eliminated, so that adhesion can be improved. Improved durability results. It has also been found that the provision of metal oxide layer portion 3c between metallic portion 3a and oxide dielectric layer 9 improves adhesion and thus durability of the mirror.

In certain example embodiments of this invention, at least a portion of the metal oxide layer portion 3b (and/or 3c) has in index of refraction (n) of from about 0.5 to 2, more preferably from 0.8 to 1.7, even more preferably from about 1.2 to 1.6 (layer portion 3c has the same index range when oxided).

In certain example embodiments of this invention, the layer portion 3b (and/or 3c) which may be of or include aluminum oxide may be oxidation graded. Oxidation graded means that the level of oxygen changes at different points in the layer portion thickness. In oxidation graded embodiments, the Al (and/or other metal M) ratio or amount should be higher at a location in layer portion 3b (and/or 3c) closer to the metallic or more metallic layer portion 3a, and lower at a location farther from 3a. The oxidation grading of layer portions 3b and/or 3c may be continuously progressive in a linear manner in certain example embodiments, or alternatively may be step-like in other example embodiments, so as to become more metallic toward metallic portion 3a. In certain example embodiments, the oxidation graded portion 3b may be substantially fully oxided immediately adjacent to the glass substrate 1 and substantially metallic immediately adjacent to the metallic or substantially metallic layer portion 3a. Likewise, if desired, the oxidation graded portion 3c may be substantially fully oxided immediately adjacent to layer 9 and substantially metallic immediately adjacent to the metallic or substantially metallic layer portion 3a.

In certain example embodiments of this invention, metallic or substantially metallic layer portion 3a may be at least about 30 nm thick and/or may represent at least about 50% (more preferably at least about 70%) of the reflective layer 3. In certain example embodiments of this invention, each of the oxide layer portions 3b and/or 3c may be from about 1-10 nm thick, more preferably from about 1-5 nm thick.

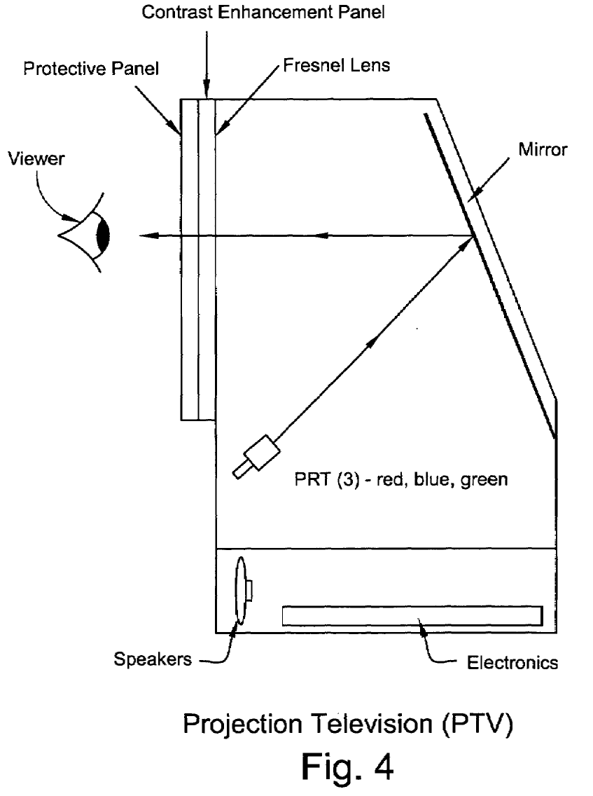

FIG. 4 is a schematic diagram illustrating the mirror of any of the embodiments discussed herein being used in the context of a projection television (PTV). Light is directed toward and reflected by the mirror which in turn directs the light toward a Fresnel lens, contrast enhancement panel, and/or protective panel after which it ultimately proceeds to a viewer. The improved features of the mirrors discussed herein enable an improved PTV to be provided.

In certain example embodiments of this invention, layer portion(s) 3b and/or 3c may be at least 50% oxidized, more preferably at least 70% oxidized, and most preferably at least 80% oxidized (even 100% oxidized in certain embodiments). Meanwhile, metallic central layer portion 3a is preferably no more than about 20% oxided/oxidized, more preferably no more than 10% oxidized, and most preferably no more than 5% oxidized (and is preferably 0% oxidized in certain example embodiments). In certain example embodiments, layer portion 3a may be purely metallic.

Other layer(s) below or above the illustrated coating may also be provided. Thus, while the layer system shown in FIG. 2 is “on” or “supported by” substrate 1 (directly or indirectly), other layer(s) may be provided therebetween. Thus, for example, other layer(s) may be provided over any of layers 3, 9 and/or 11 in certain embodiments of this invention. Also, one of layers 9 and 11 may be removed in certain example instances. Other materials may also be used. The term “between” as used herein does not mean that a layer “between” other layers must contact those other layers. Moreover, the term “on” as used herein simply means that a layer “on” a substrate is supported by the substrate regardless of whether other layer(s) are located between the substrate and that layer.

By arranging the respective materials and indices of refraction “n” of the example layers discussed above, it is possible to achieve a scratch and/or corrosion resistant, and thus durable, first surface mirror. Moreover, the first surface mirror may have a visible reflection of at least about 80%, more preferably of at least about 85%, still more preferably of at least 90%, and even at least about 95% in certain embodiments of this invention. Moreover, the mirror has a visible transmission of no more than about 7%, more preferably no more than about 5%, and most preferably no more than about 3% or 2% in certain example embodiments of this invention.

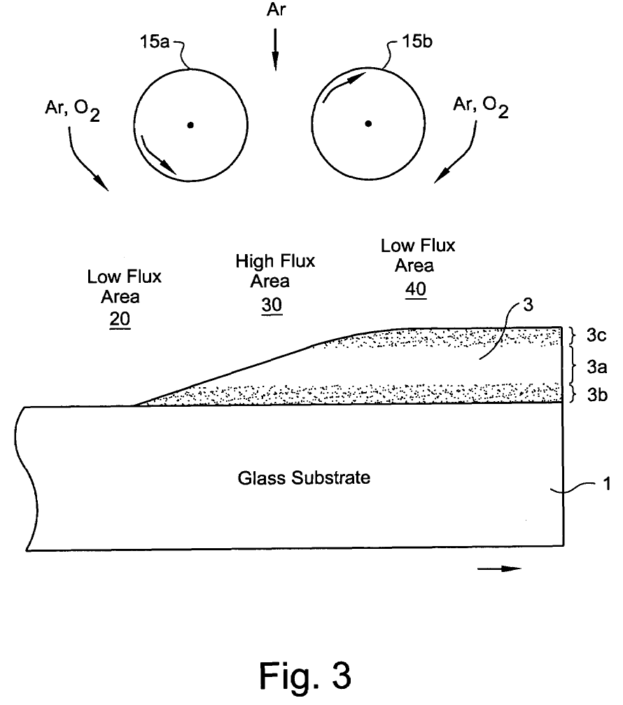

Referring to FIG. 3, an example method of making a first surface mirror of FIG. 2 will now be described (note: in FIG. 3 the thickness of reflecting layer 3 increases from left to right because the glass substrate 1 is proceeding in that direction at a point in time beneath the rotating sputtering targets 15a, 15b in the direction of the horizontal arrow). For purposes of example only, FIG. 3 illustrates first and second rotating magnetron sputtering targets 15a and 15b located above the glass substrate 1 for depositing reflective layer 3 so as to have layer portions 3a-3c (e.g., reflective layer 3 may be based on Al when using Al sputtering targets 15a, 15b). Of course, different numbers of targets may be used in other embodiments.

In an in-line sputtering apparatus, the deposition rate of a layer starts very slowly in the first low flux area 20 when a part of the underlying substrate 1 approaches the metal cathode(s)/target(s) 15, and gradually reaches a peak layer forming rate in the high flux area 30 as that part of the substrate 1 makes its way to a position directly under the cathode(s)/target(s) 15. After that part of the substrate 1 leaves the high flux area 30 under the cathode(s)/target(s) 15, the deposition rate for the layer gradually diminishes as that part of the substrate 1 reaches and proceeds through the second low flux area 40 which is typically located slightly beyond the target(s) 15.

Taking these areas of varying flux into account, FIG. 3 illustrates that the layer 3 structure 3a-3c of FIG. 2 can be made by introducing a small amount/dose of oxygen gas (preferably along with an inert gas such as argon) into the first and/or second low flux areas 20 and/or 40. As shown in FIG. 3, argon (Ar) and oxygen (O₂) gases are introduced into each low flux area 20, 40 proximate the front side of first target 15a and proximate the rear or end side of second target 15b. In the FIG. 3 embodiment, Ar gas (but not oxygen gas) is introduced between the targets 15a, 15b so as to be directed toward the high flux area 30, thereby minimizing the amount of oxygen gas in high flux area 30. In such a manner, the reflective layer 3 structure 3a-3c of FIGS. 2-3 can be formed in an easy and efficient manner.

Due to the different deposition rates between the different regions 20, 30 and 40 (highest deposition rate proximate high flux area 30, and lowest deposition rates proximate low flux areas 20 and 40), the reflective layer 3 grows at a very slow rate in the low flux areas 20 and 40, and at a very fast or maximum rate in the high flux area 30. The metallic layer portion 3a (e.g., Al) is formed in the high flux area 30, and the metal oxide layer portions 3b and 3c (e.g., Al oxide) are formed in the low flux areas 20 and 40 respectively. This enables reflective layer 3, including oxidation grading between layer portions 3a-3c, to be formed without needing an additional sputtering target(s) directed toward each metal oxide portion, which can significantly reduce hardware costs and potentially frees cathode positions for other layer(s) in that or other coating(s). In the high flux region 30 directly under the cathode(s)/target(s), since the deposition rate here is high, this portion of the reflective layer 3 contains little or no oxygen.

As will be appreciated from the figures, other gas(es) (e.g., an inert gas such as Ar) are also used in combination with the oxygen in the low flux areas 20, 40; in certain example embodiments of this invention the ratio of argon gas to oxygen gas (argon:oxygen) in regions 20 and 40 is from 2:1 to 20:1, more preferably from 3:1 to 10:1. Thus, more inert gas than reactive oxygen gas is typically provided in the low flux areas 20, 40. Amounts of oxygen gas used in regions 20, 40 according to certain embodiments of this invention are not enough to cause significant oxidation in central layer portion 3a of reflective layer 3; however, due to the effective slow deposition rates in the low flux areas as the substrate approaches and leaves the cathode(s)/target(s) T, the upper/top and lower/bottom layer portions 3c and 3b of layer 3 may still be significantly oxidized and can serve to improve durability of the mirror as explained herein.

In certain example instances, the amount of oxygen gas used in the low flux areas 20 and/or 40 may be used in determining the thickness of oxide layer portions 3b and/or 3c relative to more metallic layer portion 3a (i.e., the more oxygen gas used in low flux areas 20 and/or 40, the thicker oxide portions 3b, 3c get and the thinner central metallic portion 3a becomes assuming a common line speed). Moreover, the thickness and oxidation amount(s) of layer portions 3b and/or 3c can also or instead be adjusted and/or influenced by chamber design, gas distribution, cathode power (kW), argon gas flow, oxygen gas flow, line speed, and/or the like. It is noted that other gases (e.g., nitrogen) may be used in combination with the oxygen and/or argon in certain embodiments of this invention. It is noted that the term “oxygen” when used to describe a gas herein includes pure O₂ gas as well as other oxygen inclusive gases such as CO₂, NO, SO₂, or the like which may also be used to introduce oxygen gas into areas 20 and/or 40 in order to form oxide layer portions 3b and/or 3c.

FIG. 3 illustrates the glass substrate 1 moving horizontally below the rotating sputtering targets 15a, 15b. However, in other example embodiments, the substrate 1 may move horizontally above the sputtering targets 15a, 15b so that the sputtering material moves upwardly from the targets to be deposited on the substrate. In still further example embodiments, the substrate may move vertically instead of horizontally, and material from the target(s) may move horizontally toward the substrate to be deposited thereon. In any event, the substrate moves past the sputtering target(s) so that the reflective layer 3 can be sputter deposited on the substrate 1. It is noted that layers 9 and/or 11 may be sputter deposited, or deposited in any other suitable manner.

FIG. 3 illustrates the two CMAG targets 15a, 15b rotating in opposite directions. However, in certain alternative example embodiments of this invention, the two targets 15a, 15b may rotate in the same direction. Moreover, instead of CMAG sputtering targets, other types of sputtering targets may instead be used in certain alternatively example embodiments of this invention.

Certain examples of this invention have been made as shown in FIG. 3, and tested. The testing (e.g., brush testing per ASTM D 2486 and/or taber testing per ASTM D 1044-99) showed that first surface mirrors made according to examples of this invention performed significantly better than their counterparts not made according to this invention. In particular, mirrors made according to examples of this invention as shown in FIG. 3 have realized much better mechanical durability (based on the brush testing and taber testing tests) than have mirrors of FIG. 1 not according to this invention.

While the invention has been described in connection with what is presently considered to be the most practical and preferred embodiment, it is to be understood that the invention is not to be limited to the disclosed embodiment, but on the contrary, is intended to cover various modifications and equivalent arrangements included within the spirit and scope of the appended claims. For example, the coatings discussed herein may in some instances be used in back surface mirror applications, different materials may be used, additional or fewer layers may be provided, and/or the like.

1. A method of making a first surface mirror, the method comprising:
causing a glass substrate to move past at least one rotating sputtering target;
sputter-depositing a reflective layer, for reflecting visible light, on the glass substrate using the at least one rotating sputtering target;
introducing at least oxygen gas into a low flux area proximate a first side of the sputtering target as the glass substrate is moving past the sputtering target, and introducing at least an inert gas into a high flux area below the sputtering target as the glass substrate is moving past the sputtering target, so as to sputter deposit the reflective layer in a manner such that the reflective layer of the mirror is oxidation graded so that the reflective layer is more oxided in an area closer to the glass substrate than in a central portion of the reflective layer; and
depositing at least a first dielectric layer on the glass substrate over at least the reflective layer.

2. The method of claim 1, wherein the central portion of the reflective layer is entirely metallic or substantially metallic, and at least part of a bottom portion of the reflective layer deposited via the low flux area is substantially oxided.

3. The method of claim 2, wherein the central portion of the reflective layer comprises aluminum, and the bottom portion of the reflective layer comprises an oxide of aluminum.

4. The method of claim 2, wherein the central portion of the reflective layer consists essentially of aluminum, and the bottom portion of the reflective layer comprises an oxide of aluminum.

5. The method of claim 1, further comprising providing the first surface mirror in a projection television apparatus.

6. The method of claim 1, wherein the reflective layer is in direct contact with the glass substrate.

7. The method of claim 1, wherein the reflective layer is formed sufficiently thick so that the mirror has a visible transmission of no more than 5%.

8. The method of claim 1, wherein the reflective layer is formed so that the mirror reflects at least about 95% of incoming visible light at about 550 nm.

9. The method of claim 1, wherein the first dielectric layer comprises silicon oxide.

10. The method of claim 9, further comprising sputter depositing a second dielectric layer comprising an oxide of titanium on the glass substrate over at least the first dielectric layer.

11. The method of claim 1, further comprising depositing a second dielectric layer on the glass substrate over at least the first dielectric layer, wherein the first and second dielectric layers are each provided on the substrate over at least the reflective layer, and wherein the second dielectric layer is an outermost layer of the first surface mirror, and wherein the second dielectric layer has an index of refraction value “n” greater than an index of refraction value “n” of the first dielectric layer.

12. The method of claim 11, wherein the second dielectric layer has an index of refraction value “n” of from about 2.2 to 2.6, and the first dielectric layer has an index of refraction value “n” of from about 1.4 to 1.6.

13. The method of claim 1, further comprising introducing at least oxygen gas into another low flux area proximate an output side of the target(s) used to form the reflective layer so as to sputter deposit the reflective layer in a manner such that an upper portion of the reflective layer is oxidation graded so that the reflective layer is more oxided in an area closer to the first dielectric layer than in the central portion of the reflective layer.

14. The method of claim 1, wherein at least first and second adjacent sputtering targets are used in sputter depositing the reflective layer on the glass substrate, wherein the low flux area is located at an input side of the first target, the high flux area is located below the first and second sputtering targets, and another low flux area is located at an output side of the second target.

15. The method of claim 14, further comprising introducing a mixture of argon and oxygen gases into the two low flux areas, and introducing argon gas with less or no oxygen gas into the high flux area.

16. A method of making a mirror, the method comprising:
causing a substrate to move past at least first and second sputtering targets, wherein a first low flux area is located at an input side of the first target, a high flux area is located below the first and second sputtering targets, and a second low flux area is located at an output side of the second target;
sputter-depositing a reflective layer, for reflecting visible light, on the substrate using at least the first and second sputtering targets;
introducing at least oxygen gas into one or both of the low flux areas and introducing an inert gas into the high flux area as the glass substrate is moving past the sputtering targets, so as to sputter deposit the reflective layer on the substrate in a manner such that the reflective layer of the mirror has a metallic or substantially metallic central portion that is formed using both of the first and second targets and a metal oxide portion located at a bottom portion and/or top portion of the reflective layer, the metal oxide portion of the reflective layer comprising an oxide of the same metal provided in the central portion of the reflective layer; and
depositing at least a first dielectric layer on the substrate over at least the reflective layer.

17. The method of claim 16, wherein at least part of the bottom portion of the reflective layer deposited via the first low flux area is substantially oxided.

18. The method of claim 16, wherein the central portion of the reflective layer consists essentially of aluminum, and the bottom and/or top portion(s) of the reflective layer comprises an oxide of aluminum.

19. The method of claim 16, wherein the reflective layer is formed sufficiently thick so that the mirror has a visible transmission of no more than 5%.
